(19) United States
(12) Patent Application Publication
(10) Pub. No.: US 2024/0319253 A1
(43) Pub. Date: Sep. 26, 2024

(54) SYSTEMS AND METHODS FOR DETERMINING A DISTANCE TO A FAULT IN HYBRID LINE SYSTEMS

(71) Applicant: General Electric Technology GmbH, Baden (CH)

(72) Inventors: Hengxu Ha, Stafford (GB); Xiaoming Li, Stafford (GB)

(73) Assignee: General Electric Technology GmbH, Baden (CH)

(21) Appl. No.: 18/188,237

(22) Filed: Mar. 22, 2023

(51) Int. Cl. G01R 31/08

(52) U.S. Cl. CPC G01R 31/088; G01R 31/085

(57) ABSTRACT

The present application provides a method for determining a distance to a fault in a hybrid lines system. The method may involve calculating, based in part on measured voltage samples and measured current samples, a first set of voltage phasors and current phasors, calculating, based in part on input line parameters, ABCD parameters associated with the hybrid lines system, calculating, based in part on the first set of voltage phasors and current phasors and the ABCD parameters, a second set of voltage phasors and current phasors, collecting, based in part on the second set of voltage phasors and current phasors, faulty phase voltage phasors and current phasors, identifying, based in part on the faulty phase voltage phasors and current phasors, the fault in a faulty section of the hybrid lines system and associated parameters, and calculating, based in part on the associated parameters, the distance to the fault.

### TECHNICAL FIELD

The present application and the resultant patent relate generally to hybrid line systems and more particularly relate to systems and methods for determining a distance to a fault in hybrid line systems.

### BACKGROUND

Generally described, fault location in cables and/or hybrid lines systems is different from fault location in transmission lines. This difference is partially due to the importance of accounting for the shunt capacitances of the cables. This difference is also partially due to the non-linear nature of the line impedances (or other line parameters) relative to the line lengths due to the distributed parameters along the lines and/or cables.

Accordingly, there is a growing need for a method to accurately calculate a distance to a fault in certain types of systems based on single-ended measurements, for examples, systems involving hybrid lines, lines systems having multiple sections, systems involving underground cables, and/or systems involving overhead lines exceeding 100 kilometers in length. This may be accomplished through the application of a network with distributed ABCD parameters (that is, ABCD transmission parameters made by distributed primary parameters of a line or a cable). A zero-sequence network with distributed ABCD parameters may be used to locate faults if the fault is a Single-Phase-to-Ground fault with higher fault resistance. A negative-sequence network with distributed ABCD parameters may be used to locate faults if the fault is a phase-to-phase fault with higher fault resistance. The benefits of using the distributed ABCD parameters include increased accuracy in zonal locations, and distance-to-fault location using the single-ended measurements with an error rate of less than 2% for both single-phase-to-ground faults and phase-to-phase(-to-ground, including three-phase) faults having a resistance of 20 Ohms and a source-impedance ratio (SIR) of 10.

The fault location remains accurate even at increased fault resistances. This is partially due to the fault location analysis accounting for the type of fault that is present, where separate fault location algorithms may be implemented for single-phase-to-ground faults and phase-to-phase(-to-ground, including three-phase) faults. This is further partially due to the fault location being calculated using the Newton-Raphson method, because the derivative of the fault location function cannot be analytically expressed. Additionally, the fault section detection process utilizes a discriminative criterion which compares calculated virtual phasors with local phasors for each section.

### SUMMARY

The present application and the resultant patent thus provide a method for determining a distance to a fault in a hybrid lines system. The method may include the steps of calculating, based at least in part on a set of measured voltage samples and a set of measured current samples, a first set of voltage phasors and a first set of current phasors; calculating, based at least in part on input line parameters associated with the hybrid lines system, ABCD parameters associated with the hybrid lines system; calculating, based at least in part on the first set of voltage phasors, the first set of current phasors, and the ABCD parameters, a second set of voltage phasors and a second set of current phasors; collecting, based at least in part on the second set of voltage phasors and the second set of current phasors, faulty phase voltage phasors and faulty phase current phasors; identifying, based at least in part on the faulty phase voltage phasors and the faulty phase current phasors, the fault in a faulty section of the hybrid lines system and parameters associated with the fault; and calculating, based at least in part on the parameters associated with the fault, the distance to the fault.

The present application and the resultant patent further provide a method for determining a distance to a fault in a hybrid lines system. The method may include the steps of: receiving a set of measured voltage samples and a set of measured current samples at a first bus of the hybrid lines system; calculating, based at least in part on the set of measured voltage samples and the set of measured current samples, a first set of voltage phasors and a first set of current phasors; receiving input line parameters associated with the hybrid lines system; calculating, based at least in part on the input line parameters, ABCD parameters associated with the hybrid lines system; calculating, based at least in part on the first set of voltage phasors, the first set of current phasors, and the ABCD parameters, a second set of voltage phasors and a second set of current phasors at a second bus of the hybrid lines system; collecting, based at least in part on the second set of voltage phasors and the second set of current phasors, faulty phase voltage phasors and faulty phase current phasors; identifying, based at least in part on the faulty phase voltage phasors and the faulty phase current phasors, the fault in a faulty section of the hybrid lines system and parameters associated with the fault; and calculating, based at least in part on the parameters associated with the fault, the distance to the fault.

The present application and the resultant patent further provide a hybrid lines system. The hybrid lines system may include a first section having a first bus and a second section having a second bus, wherein a first set of voltage phasors and a first set of current phasors are calculated based at least in part on a set of measured voltage samples and a set of measured current samples associated with the first section, and wherein ABCD parameters associated with the hybrid lines system are calculated based at least in part on input line parameters associated with the hybrid lines system, and wherein a second set of voltage phasors and a second set of current phasors associated with the second section are calculated based at least in part on the first set of voltage phasors, the first set of current phasors, and the ABCD parameters, and wherein faulty phase voltage phasors and faulty phase current phasors are collected based at least in part on the second set of voltage phasors and the second set of current phasors, and wherein a fault in a faulty section of the hybrid lines system and parameters associated with the fault are identified based at least in part on the faulty phase voltage phasors and the faulty phase current phasors.

These and other features and improvements of this application and the resultant patent will become apparent to one of ordinary skill in the art upon review of the following detailed description when taken in conjunction with the several drawings and the appended claims.

### BRIEF DESCRIPTION OF THE DRAWINGS

FIG. 1 is a schematic diagram of an algorithm for calculating a distance to a fault based on ABCD parameters, in accordance with one or more example embodiments of the disclosure.

FIG. 2 is a schematic diagram of a hybrid line system, in accordance with one or more example embodiments of the disclosure.

FIG. 3A is a schematic diagram of an algorithm for performing phasor calculations, in accordance with the algorithm of FIG. 1.

FIG. 3B is a schematic diagram of an algorithm for performing phasor calculations, in accordance with the algorithm of FIG. 1.

FIG. 4 is a schematic diagram of an algorithm for performing phasor calculations at a next bus based on the ABCD parameters, in accordance with the algorithm of FIG. 1.

FIG. 5 is a schematic diagram of an algorithm for collecting faulty phasors, in accordance with the algorithm of FIG. 1.

FIG. 6A is a schematic diagram of an algorithm for identifying a faulty section, in accordance with the algorithm of FIG. 1.

FIG. 6B is a schematic diagram of an algorithm for identifying a faulty section, in accordance with the algorithm of FIG. 1.

FIG. 7 is a flow chart depicting a calculation of a distance to a fault, in accordance with the algorithm of FIG. 1.

### DETAILED DESCRIPTION

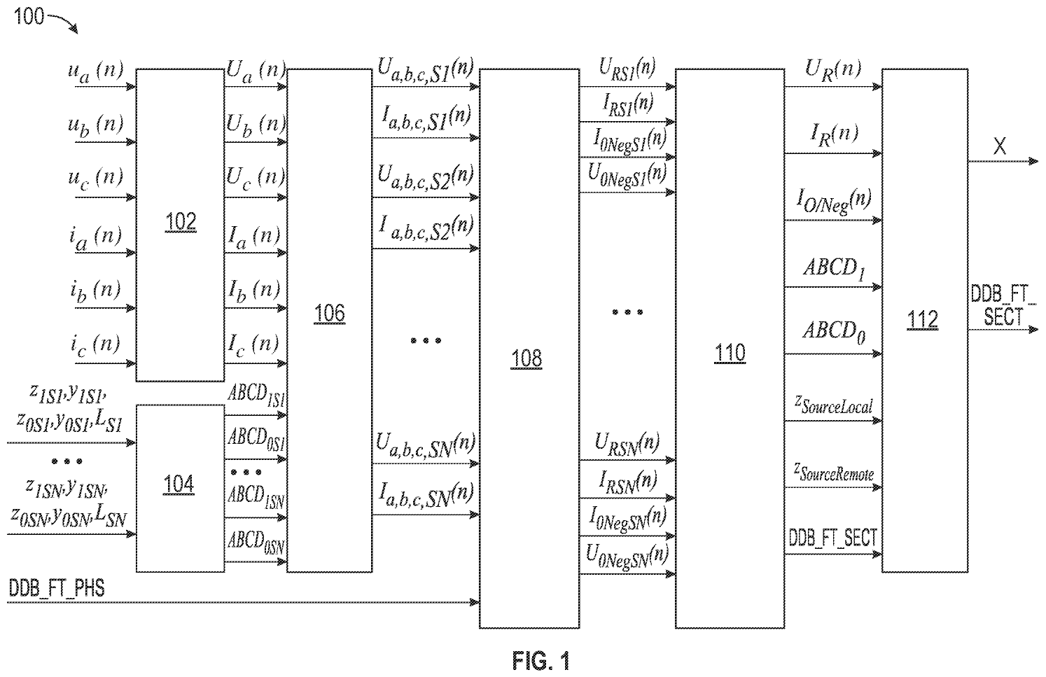

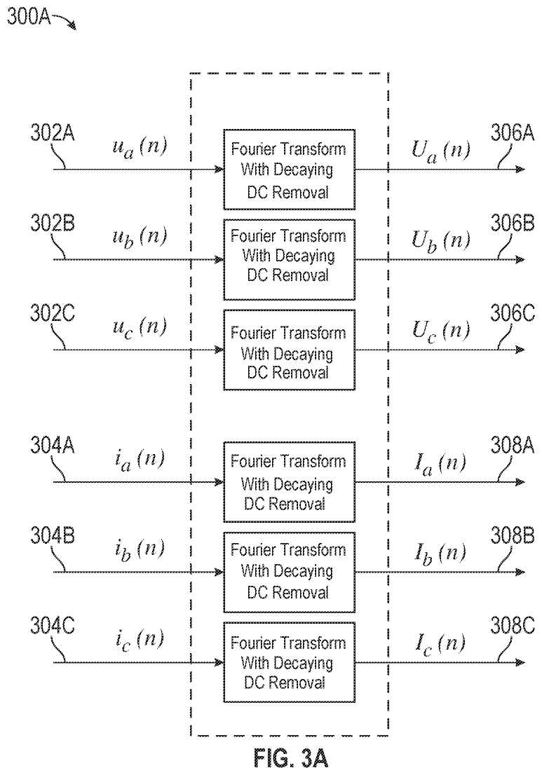

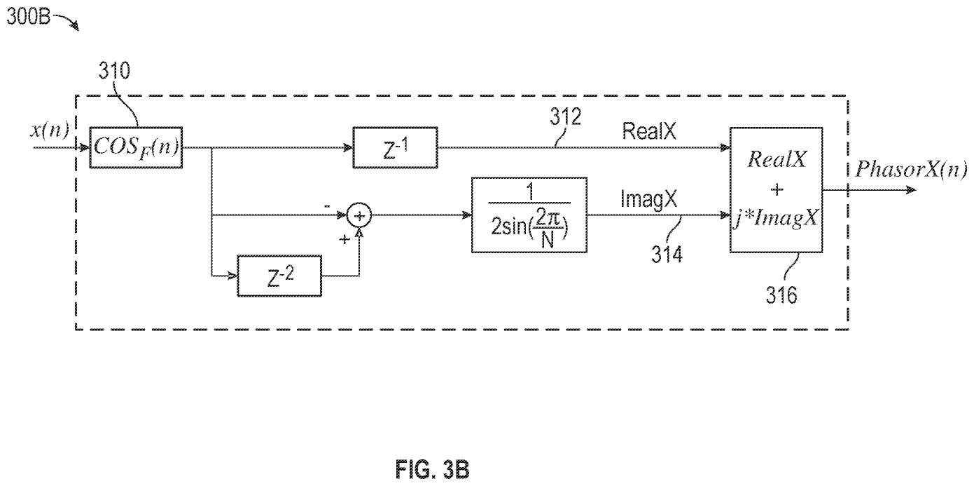

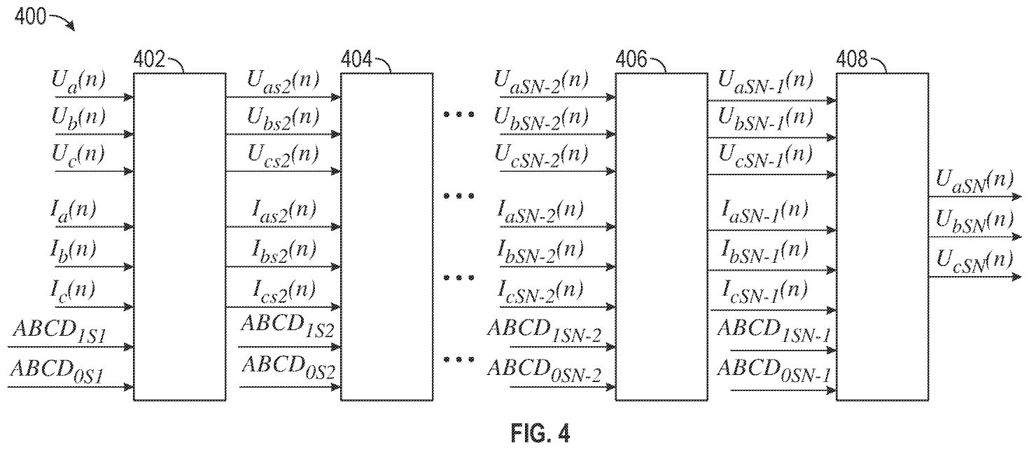

Referring now to the drawings, in which like numerals refer to like elements throughout the several views, FIG. 1 is a schematic diagram 100 for calculating a distance to a fault based on ABCD parameters. The schematic diagram 100 may be applicable to fault distance calculations for multi-section hybrid overhead lines or cables. At block 102, voltage phasors and current phasors may be calculated by applying a Fourier transform with a decaying DC removal component to single-ended measured voltage and current samples. This process may be further depicted in FIGS. 3A-B. At block 104, positive-sequence and zero-sequence ABCD parameters for each section of the hybrid lines system may be calculated based on line parameters of the corresponding section. The line parameters may include positive-sequence and zero-sequence series impedances and shunt admittances per length of each corresponding section. The line parameters may be input by a user. This process may be further depicted in FIG. 4.

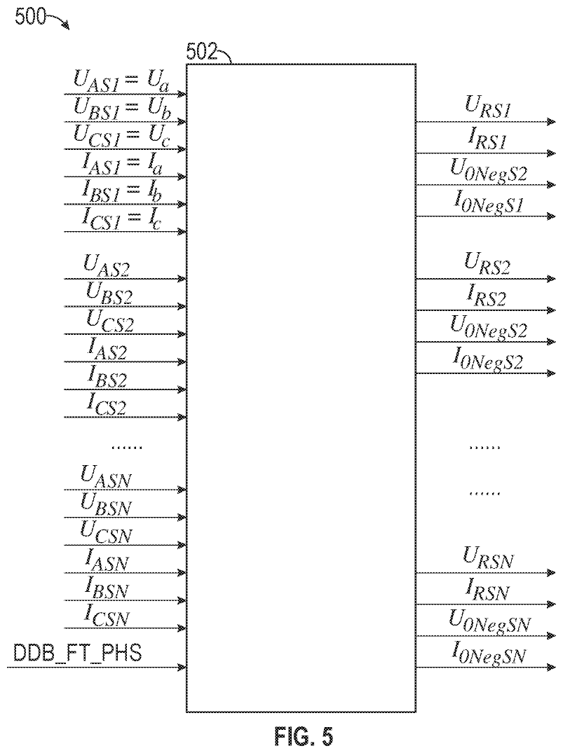

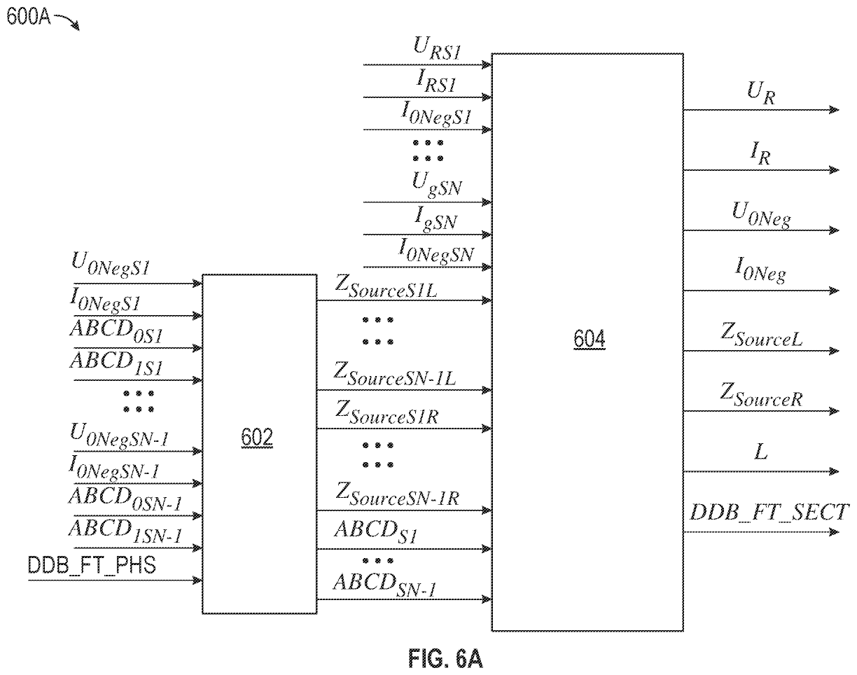

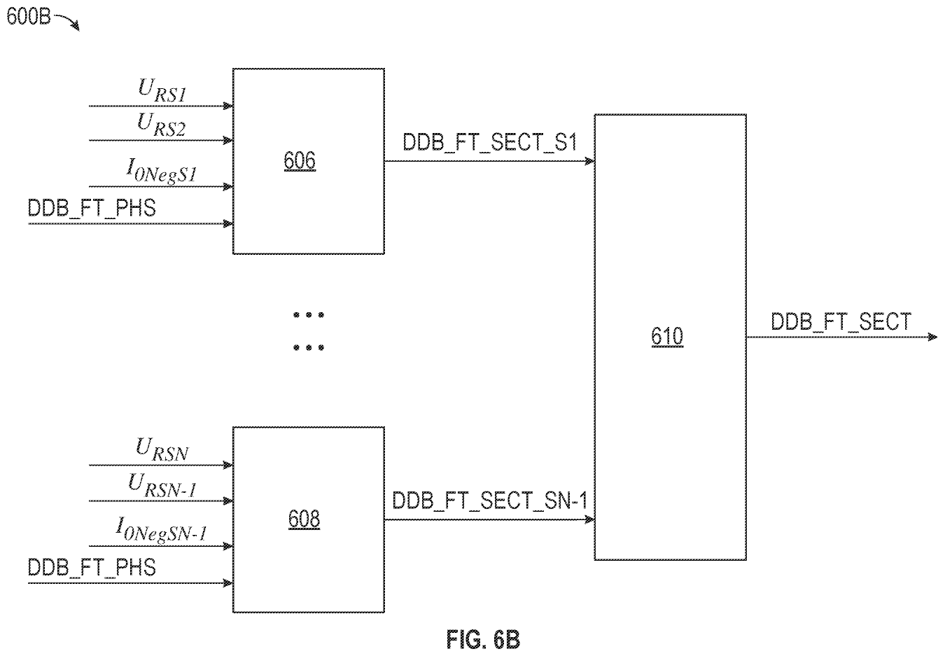

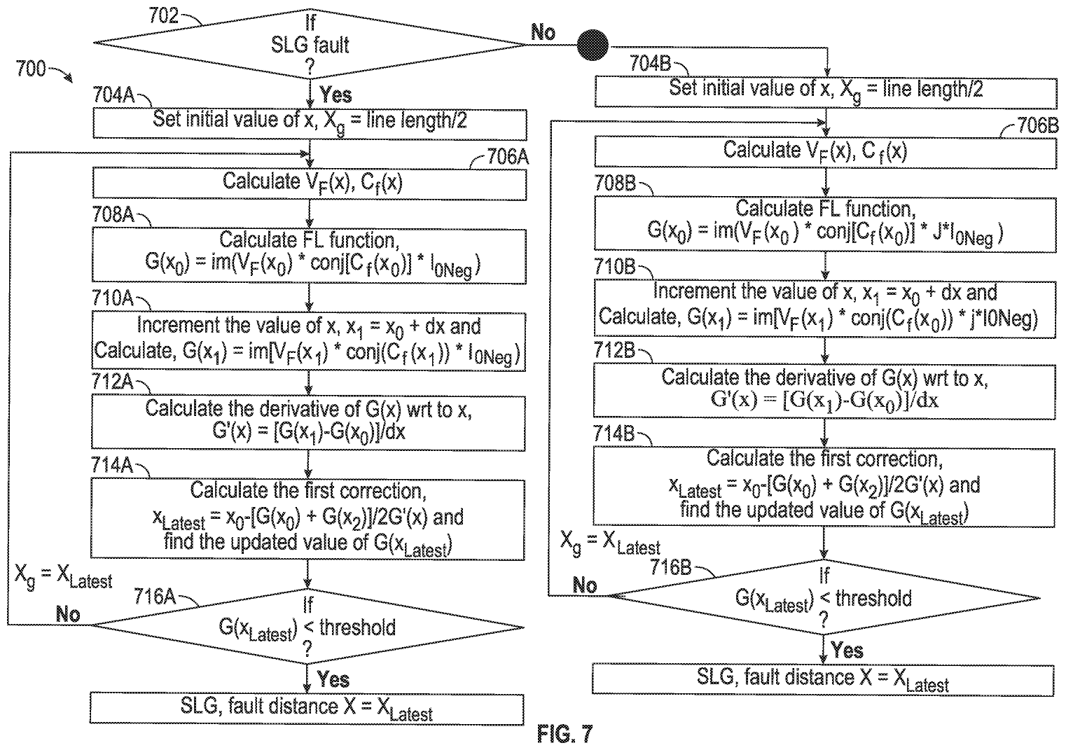

At block 106, voltage and current phasors of a next bus may be calculated based on voltage and current phasors from a bus of one terminal calculated at block 102 and the ABCD parameters calculated at block 104. Additionally, the negative-sequence and zero-sequence source impedances of each bus may also be calculated. At block 108, faulty phase voltage phasors and current phasors may be collected, along with the corresponding parameters for the faulty phase voltage phasors and current phasors. This process may be further depicted in FIG. 5. At block 110, the faulty section may be identified based on a comparison of the calculated faulty phase voltage phasors with each other or a comparison of the calculated faulty phase voltage phasors with a corresponding section's zero-sequence current. Once the faulty section has been identified, the corresponding voltage phasors and current phasors, and corresponding parameters, may be collected. This process may be further depicted at FIGS. 6A-B. At block 112, the distance to the fault is calculated by means of an ABCD parameter-based fault location algorithm based on the faulty phase voltage phasors and current phasors that have been identified. This process may be further depicted at FIG. 7.

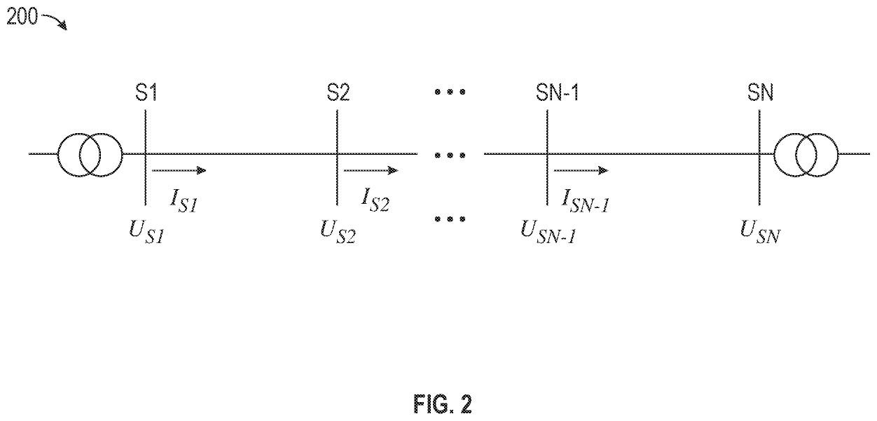

FIG. 2 is a schematic diagram 200 of a hybrid line system. As depicted in FIG. 2, a hybrid lines system may have N−1 sections. Accordingly, Section 1 (S1) may be associated with a particular voltage U_{S1} and current I_{S1}. Section 2 (S2) may be associated with a particular voltage U_{S2} and current I_{S2}. Each subsequent section may be associated with a particular voltage U_{Sk} and current I_{Sk}, where k represents a kth section. The last section (SN−1) may be associated with a particular voltage U_{SN-1} and current I_{SN-1}. The last section (SN−1) may end at bus SN, which may be associated with a particular voltage U_{SN}.

FIG. 3A is a schematic diagram 300A of an algorithm for performing phasor calculations, in accordance with the algorithm depicted in FIG. 1. The algorithm for performing phasor calculations may be applied at block 102 in FIG. 1. The algorithm may perform phasor calculations by performing a Fourier transform with decaying DC removal. At a local end, samples of each phase voltage and phase current may be measured. The samples may include a three-phase voltage, such as uₐ(n) 302A, u_{b}(n) 302B, and u_{c}(n) 302C, and a three-phase current, such as iₐ(n) 304A, i_{b}(n) 304B, and i_{c}(n) 304C. The three-phase voltage 302A-C and the three-phase voltage 304A-C may be inputs to the algorithm. After undergoing the Fourier transform with a decaying DC removal component, where uₐ(n) 302A, u_{b}(n) 302B, u_{c}(n) 302C, iₐ(n) 304A, i_{b}(n) 304B, and i_{c}(n) 304C are the respective inputs, the algorithm may output uₐ(n) 306A, u_{b}(n) 306B, u_{c}(n) 302C, iₐ(n) 308A, i_{b}(n) 308B, and i_{c}(n) 308C respectively. The outputs Uₐ(n) 306A, U_{b}(n) 306B, and U_{c}(n) 302C may represent a set of voltage phasors, while the outputs iₐ(n) 308A, i_{b}(n) 308B, and i_{c}(n) 308C may represent a set of current phasors.

FIG. 3B is a further schematic diagram 300B for performing phasor calculations, in accordance with the algorithm depicted in FIG. 1. More specifically, FIG. 3B depicts the process of performing a Fourier transform with a decaying DC removal component. First, an input x(n) (for example, uₐ(n) 302A, u_{b}(n) 302B, u_{c}(n) 302C, iₐ(n) 304A, i_{b}(n) 304B, or i_{c}(n) 304C) may be applied to a cosine filter COSA(n) 310. The coefficients of the cosine filter 310 may be as follows:

$${COS}_{F} ( n ) = \frac{2}{N} cos ( \frac{2 π n - π}{N} ) , n = 1 , 2 , … , N$$

where N represents the number of samples per cycle. The output of the cosine filter 310 may then be as follows:

$$y ( n ) = {\sum }_{k = 1}^{N} x ( n - k + 1 ) * {COS}_{F} ( k )$$

The output of the cosine filter 310 may be used to determine a real component 312 of a phasor and an imaginary component 314 of the phasor. The real component 312 may be determined as follows:

$$RealX ( n ) = y ( n - 1 )$$

Thus, the real component 312 may be determined based in part on the application of a z⁻¹ function to an output of the cosine filter 310. The imaginary component 314 may be determined as follows:

$$ImagX ( n ) = \frac{1}{2 sin ( \frac{2 π}{N} )} * ( y ( n - 2 ) - y ( n ) )$$

Thus, the imaginary component 314 may be determined based in part on the application of a z⁻² function to an output of the cosine filter 310. A phasor output component 316 may then receive the real component 312 (RealX(n)) and the imaginary component 314 (ImagX(n)) and output a phasor

$$PhasorX ( n ) = RealX ( n ) + j * ImagX ( n )$$

The phasor PhasorX(n) may represent voltage phasors and/or current phasors. Accordingly, the algorithm depicted in FIG. 3B may be used to output voltage phasors Uₐ(n) 306A, U_{b}(n) 306B, and U_{c}(n) 302C, and current phasors Iₐ(n) 308A, I_{b}(n) 308B, and I_{c}(n) 308C, which are depicted in FIG. 3A.

FIG. 4 is a schematic diagram 400 of an algorithm for performing phasor calculations at a next bus based on the ABCD parameters. In order to perform the phasor calculations at the next bus based on the ABCD parameters, the ABCD parameters must first be calculated. A line length of each line section L_{Sk} may be identified, where Sk is the kth section, and k=1, 2, . . . , N−1. The line length of each line section L_{Sk} may be input by a user. Positive-sequence and zero-sequence impedances and admittances per length of each line section may also be identified and input by a user. Lengths may be indicated in kilometers, meters, or miles. The positive-sequence impedance may be noted as z_{1Sk}, the zero-sequence impedance may be noted as z_{0Sk}, the positive-sequence admittance may be noted as y_{1Sk}, and the zero-sequence admittance may be noted as y_{0Sk}. If a line section L_{Sk} is an overhead line, as opposed to a cable, the positive-sequence and zero-sequence admittances y_{1Sk} and y_{0Sk} need not be input by a user, because the positive-sequence and zero-sequence admittances y_{1Sk} and y_{0Sk} may be calculated as follows:

$${y}_{1 S k} = \frac{4 {π}^{2} {f}^{2}}{{c}_{1}^{2} i m a g ( {z}_{1 S k} )}$$

$$And$$

$${y}_{0 S k} = \frac{4 {π}^{2} {f}^{2}}{{c}_{0}^{2} i m a g ( {z}_{0 S k} )}$$

where f is the frequency of the system, which may be 50 Hz, 60 Hz, where c₁=2.95×10⁵ km/s and c₁ represents the positive-sequence traveling wave speed, and c₀=2.8×10⁵ km/s and c₀ represents the zero-sequence traveling wave speed.

After the line length of each line section L_{Sk} and the positive-sequence and zero-sequence impedances and admittances per length z_{1Sk}, z_{0Sk}, y_{1Sk}, and y_{0Sk} have been input and/or calculated, the positive-sequence ABCD parameters and the zero-sequence ABCD parameters may be calculated. The positive-sequence ABCD parameters, which are A_{1Sk}, B_{1Sk}, C_{1Sk}, and Disk, may be calculated as follows:

$$\begin{matrix}{A}_{1 S k} = cosh ( {γ}_{1 S k} {L}_{S k} ) \\ {B}_{1 S k} = - {Z}_{C 1 S k} sinh ( {γ}_{1 S k} {L}_{S k} ) \\ {C}_{1 S k} = \frac{{B}_{1 S k}}{{Z}_{C 1 S k}^{2}} \\ {D}_{1 S k} = {A}_{1 S k} \\ where {γ}_{1 S k} = \sqrt{{z}_{1 S k} {y}_{1 S k}} and {Z}_{C 1 S k} = \sqrt{\frac{{z}_{1 S k}}{{y}_{1 S k}}} .\end{matrix}$$

The zero-sequence ABCD parameters, which are A_{0Sk}, B_{0Sk}, C_{0Sk}, and D_{0Sk}, may be calculated as follows:

$$\begin{matrix}{A}_{0 S k} = cosh ( {γ}_{0 S k} {L}_{S k} ) \\ {B}_{0 S k} = - {Z}_{C 0 S k} sinh ( {γ}_{0 S k} {L}_{S k} ) \\ {C}_{0 S k} = \frac{{B}_{0 S k}}{{Z}_{C 0 S k}^{2}} \\ {D}_{0 S k} = {A}_{0 S k} where {γ}_{o S k} = \sqrt{{z}_{0 S k} {y}_{0 S k}} and {Z}_{C 0 S k} = \sqrt{\frac{{z}_{0 S k}}{{y}_{0 S k}}} .\end{matrix}$$

As depicted in FIG. 4, the positive-sequence and the zero-sequence ABCD parameters, the voltage phasors (for example, Uₐ(n) 306A, U_{b}(n) 306B, and U_{c}(n) 306C, as depicted in FIG. 3A) and the current phasors (for example, Iₐ(n) 308A, I_{b}(n) 308B, and I_{c}(n) 308C, as depicted in FIG. 3A) may serve as an input to an ABCD algorithm component. The ABCD algorithm component may receive the inputs and apply the ABCD algorithm to calculate voltage phasors and current phasors at a next bus.

In order to calculate the voltage phasors and current phasors at the next bus, the ABCD algorithm component may execute an ABCD algorithm as follows:

$$\begin{matrix}{U}_{a S k + 1} = {A}_{1 S k} {U}_{a S k} + {B}_{1 S k} {I}_{a S k} + ( {A}_{0 S k} - {A}_{1 S k} ) {U}_{0 S k} + ( {B}_{0 S k} - {B}_{1 S k} ) {I}_{0 S k} \\ {U}_{b S k + 1} = {A}_{1 S k} {U}_{b S k} + {B}_{1 S k} {I}_{b S k} + ( {A}_{0 S k} - {A}_{1 S k} ) {U}_{0 S k} + ( {B}_{0 S k} - {B}_{1 S k} ) {I}_{0 S k} \\ {U}_{c S k + 1} = {A}_{1 S k} {U}_{c S k} + {B}_{1 S k} {I}_{c S k} + ( {A}_{0 S k} - {A}_{1 S k} ) {U}_{0 S k} + ( {B}_{0 S k} - {B}_{1 S k} ) {I}_{0 S k} \\ {I}_{a S k + 1} = {C}_{1 S k} {U}_{o S k} + {D}_{1 S k} {I}_{o S k} + ( {C}_{0 S k} - {C}_{1 S k} ) {U}_{0 S k} + ( {D}_{0 S k} - {D}_{1 S k} ) {I}_{0 S k} \\ {I}_{b S k + 1} = {C}_{1 S k} {U}_{b S k} + {D}_{1 S k} {I}_{b S k} + ( {C}_{0 S k} - {C}_{1 S k} ) {U}_{0 S k} + ( {D}_{0 S k} - {D}_{1 S k} ) {I}_{0 S k} \\ {I}_{c S k + 1} = {C}_{1 S k} {U}_{c S k} + {D}_{1 S k} {I}_{c S k} + ( {C}_{0 S k} - {C}_{1 S k} ) {U}_{0 S k} + ( {D}_{0 S k} - {D}_{1 S k} ) {I}_{0 S k} \\ where {U}_{0 S k} = \frac{{U}_{a S k} + {U}_{b S k} + {U}_{c S k}}{3} and {I}_{0 S k} = \frac{{I}_{a S k} + {I}_{b S k} + {I}_{c S k}}{3} .\end{matrix}$$

For example, the first ABCD algorithm component 402, the second ABCD algorithm component 404, the third ABCD algorithm component 406, and the fourth ABCD algorithm component 408 may apply the ABCD algorithm as described herein.

Accordingly, the ABCD algorithm may be used to calculate voltage phasors and current phasors at a next bus in a hybrid lines system. For example, referring back to FIG. 2, a hybrid line system may have a Section 1 (S1) having a three-phase voltage of U_{S1} and a three-phase current of I_{S1}, a Section 2 (S2) having a three-phase voltage of U_{S2} and a three-phase current of I_{S2}, any number of subsequent sections, a last section (SN−1) having a three-phase voltage of U_{SN-1} and a three-phase current of I_{SN-1}, and where the last section ends at bus SN with a three-phase voltage of U_{SN}. As such, at S1, the first ABCD algorithm component 402 may receive three voltage phasors corresponding to the voltage U_{S1} (U_{aS1}(n), U_{bS1}(n), and U_{cS1}(n)), three current phasors corresponding to the current I_{S1} (I_{aS1}(n), I_{bS1}(n), and I_{cS1}(n)), the positive-sequence ABCD parameters for S1 (ABCD_{1S1}), and the zero-sequence ABCD parameters for S1 (ABCD_{0S1}) as inputs. The first ABCD algorithm component 402 may then apply the ABCD algorithm to calculate the three voltage phasors at S2 (U_{aS2}(n), U_{bS2}(n), and U_{cS2}(n)) and the three current phasors at S2 (I_{aS2}(n), I_{bS2}(n), and I_{cS2}(n)).

Subsequently, the voltage phasors at S2 (U_{aS2}(n), U_{bS2}(n), and U_{cS2}(n)) and the current phasors at S2 (I_{aS2}(n), I_{bS2}(n), and I_{cS2}(n)) may be used as inputs to the second ABCD algorithm component 404. The second ABCD algorithm component 404 may also receive as inputs the positive-sequence ABCD parameters at S2 (ABCD_{1S2}), and the zero-sequence ABCD parameters at S2 (ABCD_{0S2}). The second ABCD algorithm component 404 may then apply the ABCD algorithm to calculate the voltage phasors and the current phasors at a subsequent section of the hybrid line system. This process may be repeated for as many sections as are present in the hybrid lines system.

As depicted in FIG. 4, the third ABCD algorithm component 406 is configured to receive as inputs the voltage phasors (U_{aSN-2}(n), U_{bSN-2}(n), and U_{cSN-2}(n)) and the current phasors (I_{aSN-2}(n), I_{bSN-2}(n), and I_{cSN-2}(n)) from the second last section SN−2. The third ABCD algorithm component 406 also receive as inputs the positive-sequence ABCD parameters at SN−2 (ABCD_{ISN-2}), and the zero-sequence ABCD parameters at SN−2 (ABCD_{OSN-2}). The third ABCD algorithm component may then apply the ABCD algorithm to calculate the voltage phasors (U_{aSN-1}(n), U_{bSN-1}(n), and U_{cSN-1}(n)) and the current phasors (I_{aSN-1}(n), I_{bSN-1}(n), and I_{cSN-1}(n)) at the last section SN−1 of the hybrid lines system.

At the end of the hybrid lines system, which is represented by point SN, the fourth ABCD algorithm component 408 is configured to receive as inputs the voltage phasors (U_{aSN-1}(n), U_{bSN-1}(n), and U_{cSN-1}(n)) and the current phasors (I_{aSN-1}(n), I_{bSN-1}(n), and I_{cSN-1}(n)) from the last section SN−1. The fourth ABCD algorithm component 408 also receive as inputs the positive-sequence ABCD parameters at SN−1 (ABCD_{ISN-1}), and the zero-sequence ABCD parameters at SN−1 (ABCD_{OSN-1}). The fourth ABCD algorithm component 408 may then apply the ABCD algorithm to calculate the voltage phasors (U_{aSN} (n), U_{bSN} (n), and U_{cSN} (n)) and the current phasors (I_{aSN}(n), I_{bSN}(n), and I_{cSN}(n)) at the last point SN of the hybrid lines system.

FIG. 5 depicts a schematic diagram 500 of an algorithm for collecting faulty phasors. After the voltage phasors and the current phasors at each bus of a hybrid line system have been calculated and/or collected, the faulty phase voltage and current phasors, along with corresponding parameters, may be collected by an external indication of a faulty phase selection, DDB_TF_PHS. The voltage phasors and the current phasors at the first bus are the phasors of the measured voltage and current at the start of the hybrid line system. The voltage phasors and the current phasors at subsequent busses are calculated using an ABCD algorithm, for example, the ABCD algorithm depicted in FIG. 4.

Accordingly, the inputs to a faulty phasors collection component 502 may include DDB_FT_PHS, which is a faulty phase indicator, and each set of voltage and current phasors that are calculated and/or collected at each bus of the hybrid line system. For example, the inputs may include U_{aS1}, U_{bS1}, U_{cS1}, I_{aS1}, I_{bS1}, and I_{cS1}, which represent the voltage and current phasors at a first section of the hybrid line system (for example, Section 1 S1 of FIG. 2). Because these phasors represent the first section of the hybrid line system, U_{aS1}, U_{bS1}, U_{cS1}, I_{aS1}, I_{bS1}, and I_{cS1} may be determined by the measured voltage and current phasors at the start of the hybrid line system. That is, U_{aS1}=Uₐ, U_{bS1}=U_{b}, U_{cS1}=U_{c}, I_{aS1}=Iₐ, I_{bS1}=I_{b}, and I_{cS1}=I_{c}. Other inputs may include the voltage and current phasors at a second section of the hybrid line system (for example, Section 2 S2 of FIG. 2), such as U_{aS2}, U_{bS2}, U_{cS2}, I_{aS2}, I_{bS2}, and I_{cS2}. Additional inputs may include the voltage and current phasors at any subsequent sections of the hybrid line system. Another input may include the voltage and current phasors at a last bus of the hybrid line system, that is, at the end of the last section of the hybrid line system. These voltage and current phasors may be represented by U_{aSN}, U_{bSN}, U_{cSN}, I_{aSN}, I_{bSN}, and I_{csN}.

After receiving the inputs, the faulty phasor collection component 502 may apply the following principles for collecting the faulty voltage and/or current phasors:

If DDB_FT_PHS indicates that a fault is a phase-A-to-ground fault, then the following equations may apply.

$$\begin{matrix}{U}_{R S k} = {U}_{a S k} ; k = 1 , 2 , … , N \\ {I}_{R S k} = {I}_{a S k} ; k = 1 , 2 , … , N \\ {U}_{0 N e g S k} = \frac{( {U}_{aSk} + {U}_{b S k} + {U}_{c S k} )}{3} \\ {I}_{0 N e g S k} = \frac{( {I}_{a S k} + {I}_{b S k} + {I}_{c S k} )}{3}\end{matrix}$$

If DDB_FT_PHS indicates that a fault is a phase-B-to-ground fault, then the following equations may apply.

$$\begin{matrix}{U}_{R S k} = {U}_{b S k} ; k = 1 , 2 , … , N \\ {I}_{R S k} = {I}_{b S k} ; k = 1 , 2 , … , N \\ {U}_{0 N e g S k} = \frac{( {U}_{aSk} + {U}_{b S k} + {U}_{c S k} )}{3} \\ {I}_{0 N e g S k} = \frac{( {I}_{a S k} + {I}_{b S k} + {I}_{c S k} )}{3}\end{matrix}$$

If DDB_FT_PHS indicates that a fault is a phase-C-to-ground fault, then the following equations may apply.

$$\begin{matrix}{U}_{R S k} = {U}_{cSk} ; k = 1 , 2 , … , N \\ {I}_{R S k} = {I}_{cSk} ; k = 1 , 2 , … , N \\ {U}_{0 N e g S k} = \frac{( {U}_{aSk} + {U}_{b S k} + {U}_{c S k} )}{3} \\ {I}_{0 N e g S k} = \frac{( {I}_{a S k} + {I}_{b S k} + {I}_{c S k} )}{3}\end{matrix}$$

If DDB_FT_PHS indicates that a fault is a phase-A-to-B fault, or a phase-A-to-B-to-ground fault, or a phase-A-to-B-to-C fault, or a phase-A-to-B-to-C-to-ground fault, then the following equations may apply.

$$\begin{matrix}{U}_{R S k} = {U}_{aSk} - {U}_{b S k} ; k = 1 , 2 , … , N \\ {I}_{R S k} = {I}_{b S k} - {I}_{b S k} ; k = 1 , 2 , … , N \\ {U}_{0 N e g S k} = \frac{( {U}_{cSk} + {α}^{2} {U}_{aSk} + α {U}_{bSk} )}{3} \\ {I}_{0 N e g S k} = \frac{( {I}_{cSk} + α {I}_{aSk} + α {I}_{bSk} )}{3}\end{matrix}$$

If DDB_FT_PHS indicates that a fault is a phase-B-to-C fault or a phase-B-to-C-to-ground fault, then the following equations may apply.

$$\begin{matrix}{U}_{R S k} = {U}_{bSk} - {U}_{cSk} ; k = 1 , 2 , … , N \\ {I}_{R S k} = {I}_{b S k} - {I}_{cSk} ; k = 1 , 2 , … , N \\ {U}_{0 N e g S k} = \frac{( {U}_{aSk} + {α}^{2} {U}_{bSk} + α {U}_{cSk} )}{3} \\ {I}_{0 N e g S k} = \frac{( {I}_{aSk} + α {I}_{bSk} + α {I}_{cSk} )}{3}\end{matrix}$$

If DDB_FT_PHS indicates that a fault is a phase-C-to-A fault or a phase-C-to-A-to-ground fault, then the following equations may apply.

$$\begin{matrix}{U}_{R S k} = {U}_{cSk} - {U}_{aSk} ; k = 1 , 2 , … , N \\ {I}_{R S k} = {I}_{cSk} - {I}_{aSk} ; k = 1 , 2 , … , N \\ {U}_{0 N e g S k} = \frac{( {U}_{bSk} + {α}^{2} {U}_{cSk} + α {U}_{aSk} )}{3} \\ {I}_{0 N e g S k} = \frac{( {I}_{bSk} + α {I}_{cSk} + α {I}_{aSk} )}{3}\end{matrix}$$

The faulty phasor collection component 502 may use the DDB_FT_PHS input and the appropriate equations in order to determine U_{RSk}, I_{RSk}, U_{ONegSk}, and I_{0NegSk} for each set of voltage and current phasors received by the faulty phasor collection component. For example, responsive to receiving U_{aS1}, U_{bS1}, U_{cS1}, I_{aS1}, I_{bS1}, and I_{cS1}, the faulty phasor collection component 502 may output U_{RS1}, I_{RS1}, U_{0Negs1}, and I_{0NegS1}. Further, responsive to receiving U_{aS2}, U_{bS2}, U_{cS2}, I_{aS2}, I_{bS2}, and I_{cS2}, the faulty phasor collection component 502 may output U_{RS2}, I_{RS2}, U_{0NegS2}, and I_{0NegS2}. Additionally, responsive to receiving U_{aSN}, U_{bSN}, U_{cSN}, L_{aSN}, I_{bSN}, and I_{cSN}, the faulty phasor collection component 502 may output U_{RSN}, I_{RSN}, U_{0NegSN}, and I_{0NegSN}.

FIG. 6A is a schematic diagram 600A of an algorithm for identifying a faulty section, for example, in a hybrid lines system. The algorithm may include a source impedance calculation component 602 and a faulty section identification and parameter collection component 604. The source impedance calculation component 602 may receive at least one set of inputs U_{0NegSk}, I_{0NegSk}, ABCD_{0Sk}, and ABCD_{1Sk}, where one set of inputs is received for each section in the hybrid lines system. For example, the source impedance calculation component 602 may receive U_{0NegS1}, I_{0NegS1}, ABCD_{0S1}, and ABCD_{1S1}, . . . , U_{0NegSN-1}, I_{0NegSN-1}, ABCD_{0SN-1}, and ABCD_{1SN-1} for a hybrid lines system having N−1 sections. The source impedance calculation component 602 may further receive DDB_FT_PHS as an input.

The source impedance calculation component 602 may use these inputs to calculate the following outputs: z_{SourceSkL} for each section, z_{SourceSkR} for each section, and ABCD_{Sk} for each section. That is, where the hybrid line system has N−1 sections, the source impedance calculation component 602 may output z_{SourceS1L}, . . . , z_{SourceSN-1L}, z_{SourceS1R}, . . . , z_{SourceSN-1R}, ABCD_{S1}, . . . , ABCDS_{N-1}, which may then serve as inputs to the faulty section identification and parameter collection component 604. The local and remote source impedances may be calculated as follows:

$$\begin{matrix}{z}_{SourceSkl} = - \frac{{U}_{0 N e g S k}}{{I}_{0 N e g S k}} \\ {z}_{SourceS ( k ) R} = \frac{{A}_{s k} {Z}_{SourceS ( k + 1 ) R} - {B}_{s k}}{{D}_{Sk} - {C}_{Sk} {Z}_{SourceS ( k + 1 ) R}} \\ {z}_{SourceS ( N - 1 ) R} = {z}_{SourceS 1 L}\end{matrix}$$

where A_{Sk}, B_{Sk}, C_{Sk}, and D_{Sk} are zero-sequence ABCD parameters of Section k if the faulty phase is indicated as a single-phase-to-ground fault, and where A_{Sk}, B_{Sk}, C_{Sk}, and D_{Sk} are positive-sequence ABCD parameters of Section k if the faulty phase is indicated as a phase-to-phase fault, a phase-to-phase-to-ground fault, a three-phase fault, or a three-phase-to-ground fault.

Other inputs to the faulty section identification and parameter collection component 604 may include the following: U_{RSk} for each section, I_{RSk} for each section, and I_{0NegSk} for each section. For example, where the hybrid line system has N−1 sections and where the N−1th section ends in bus SN, the faulty section identification and parameter collection component 604 may receive the following inputs: U_{RS1}, I_{RS1}, I_{0NegS1}, . . . , U_{RSN}, I_{RSN}, and I_{0NegSN}. These inputs may be output by a faulty phasor collection component, for example, the faulty phasor collection component 502 depicted in FIG. 5. The faulty section identification and parameter collection component 604 may then determine the sections in the hybrid lines system that are faulty.

An algorithm 600B for identifying a faulty section is depicted in FIG. 6B. The faulty section identification and parameter collection component 604 may include a faulty section identification component for each section in the hybrid lines system. For example, the faulty section identification and parameter collection component 604 may include a faulty S1 section identification component 606, . . . , and a faulty SN−1 section identification component 608. Each of the faulty section identification components for each section may receive as inputs U_{RSk}, U_{RSk+1}, I_{0NegSk}, and DDB_FT_PHS. For example, the faulty S1 section identification component 606 may receive U_{RS1}, U_{RS2}, I_{0NegS1}, and DDB_FT_PHS as inputs. The faulty SN−1 section identification component 608 may receive U_{RSN-1}, U_{RSN}, I_{0NegSN-1}, and DDB_FT_PHS as inputs.

Each of the faulty section identification components for each section in the hybrid lines system may be configured to generate an output DDB_FT_SECT_Sk, which represents whether the section is faulty or not faulty. For example, the faulty S1 section identification component 606 may output DDB_FT_SECT_S1, which determines if S7 is faulty, and the faulty SN−1 section identification component 608 may output DDB_FT_SEC_SN−1, which determines if SN−1 is faulty. In order to generate the output DDB_FT_SECT_Sk, each of the faulty section identification components (e.g., faulty S1 section identification component 606 and faulty SN−1 section identification component 608), the following conditions may apply. If the fault is a phase-to-phase fault, a phase-to-phase-to-ground fault, or a three-phase fault, apply the following condition:

$$\frac{real ( {U}_{S k + 1} * conj ( {U}_{S k} ) )}{\vert {U}_{sk + 1} {U}_{s k} \vert} < - 0.001$$

where U_{Sk} is the voltage of the kth bus, and U_{Sk+1} is the voltage of the (k+1)th bus. If the fault is a single-phase-to-ground fault, apply the following condition:

$$\frac{i m a g ( {U}_{S k + 1} * c o nj ( {I}_{0 S k} exp ( j * Alpha ) ) )}{\vert {U}_{S k + 1} {I}_{0 S k} \vert} < - 0.001$$

where U_{Sk+1} is the voltage of the (k+1)th bus, I_{0Sk} is the zero-sequence current at the kth bus, and Alpha is a compensation angle, where

$$Alpha = angle ( - {C}_{Sk} * {z}_{SourceL} + {D}_{Sk} + \frac{{A}_{Sk} * {z}_{SoutceSkL} - {B}_{Sk}}{{Z}_{SourceSkR}} )$$

If the applicable condition is valid, then the output DDB_FT_SECT_Sk may be set to 1.

The various DDB_FT_SECT_Sk, where k=1, 2, . . . , N−1, outputs may be input into a final logic component 610, which may be configured to determine the faulty sections in the hybrid lines system. The final logic component 610 may generate a table of DDB_FT_SECT_Sk values. Further, the final logic component 610 may determine that a kth section is faulty if DDB_FT_SECT_Sk=1 and DDB_FT_SECT_Sk-1=0. Accordingly, the final logic component 610 may output DDB_FT_SECT, which identifies the faulty section(s) in the hybrid lines system.

Returning to FIG. 6A, after identifying the faulty section(s), the faulty section identification and parameter collection component 604 may then output the following for each faulty section: U_{R}, I_{R}, U_{0Neg}, I_{0Neg}, z_{SourceL}, z_{SourceR}, L, and DDB_FT_SECT. These outputs are representative of the identification of the faulty section, the corresponding voltage, the corresponding current, and parameters associated with the faulty section that may be used to calculate a distance to the fault. If a kth section is identified as a faulty section, the faulty section identification and parameter collection component 604 may generate the following output parameters: U_{R}=U_{RSk}, I_{R}=I_{RSk}, U_{0Neg}=U_{0NegSk}, I_{0Neg}=I_{0NegSk}, ABCD=ABCD_{Sk}, L=L_{Sk}, z_{SourceL}=z_{SourceSkL}, and z_{SourceR}=z_{SourceSkR}. Other outputs may include positive-sequence and zero-sequence ABCD parameters associated with each faulty section.

The output parameters may then be used to calculate a distance to the fault through the application of the following formula:

$$G ( x ) = imag [ {V}_{F} ( x ) conj ( {C}_{f} ( x ) {I}_{0 Neg} ] = 0$$

If the fault is indicated to be a single-phase-to-ground fault, then the voltage at the fault point is calculated as

$${V}_{F} ( x ) = {A}_{1} ( x ) {U}_{R} + {B}_{1} ( x ) {I}_{R} + ( {A}_{0} ( x ) - {A}_{1} ( x ) ) {U}_{0 Neg} + ( {B}_{0} ( x ) - {B}_{1} ( x ) ) {I}_{0 Neg}$$

The fault current distribution factor C_{f}(x) may be calculated as

$${C}_{f} ( x ) = ( - {z}_{SourceL} {C}_{0} ( x ) + {D}_{0} ( x ) ) + \frac{( - {z}_{SourceR} {C}_{0} ( l - x ) + {D}_{0} ( l - x ) ) ( - {z}_{SourceL} {A}_{0} ( x ) + {B}_{0} ( x ) )}{- {z}_{SourceR} {A}_{0} ( l - x ) + {B}_{0} ( l - x )}$$

If the fault is indicated to be a phase-to-phase fault, a phase-to-phase-to-ground fault, a three-phase fault, or a three-phase-to-ground fault, then the voltage at the fault point may be calculated as

$${V}_{F} ( x ) = {A}_{1} ( x ) {U}_{R} + {B}_{1} ( x ) {I}_{R}$$

The fault current distribution factor C_{f}(x) may be calculated as

$${C}_{f} ( x ) = ( - {z}_{SourceL} {C}_{1} ( x ) + {D}_{1} ( x ) ) + \frac{( - {z}_{SourceR} {C}_{1} ( l - x ) + {D}_{1} ( l - x ) ) ( - {z}_{SourceL} {A}_{1} ( x ) + {B}_{1} ( x ) )}{- {z}_{SourceR} {A}_{1} ( l - x ) + {B}_{1} ( l - x )}$$

Because G(x) is a non-linear equation, it may be solved using the Newton-Raphson method.

FIG. 7 depicts a flow chart 700 for calculating a distance to a fault. First, voltage and current phasors of the faulted section, the length and the ABCD parameters of the faulted section, the local and remote equivalent source impedances of the faulted section, and the faulted phase information of the faulted section must be known. At block 702, it may be determined if the fault is a single-line-to-ground (SLG) fault. If the fault is a single-line-to-ground (SLG) fault, then, at block 704A, the initial value of x, x₀, may be set to half of the line length. At block 706A, V_{F}(x) and C_{f}(x) may be calculated as follows in the case of a single-line-to-ground fault:

$${V}_{F} ( x ) = {A}_{1} ( x ) {U}_{R} + {B}_{1} ( x ) {I}_{R} + ( {A}_{0} ( x ) - {A}_{1} ( x ) ) {V}_{0 NEg} + ( {B}_{0} ( x ) - {B}_{0} ( x ) ) ) * {I}_{0 Neg}$$

$${C}_{f} ( x ) = ( - {Z}_{M 0} {C}_{0} ( x ) + {D}_{0} ( x ) ) + \frac{( - {Z}_{N 0} {C}_{0} ( x ) + {D}_{0} ( x ) ) ( - {Z}_{M 0} {A}_{0} ( x ) + {B}_{0} ( x ) )}{- {Z}_{N 0} {A}_{0} ( x ) + {B}_{0} ( x )}$$

At block 708A, the function for G(x₀) may be calculated. That is,

$$G ( {x}_{0} ) = imag ( {V}_{F} ( {x}_{0} ) * conj ( {C}_{f} ( {x}_{0} ) ) ) * {I}_{0 Neg} )$$

may be calculated.

At block 710A, the value of x may be incremented from x₀ to x₁, where x₁=x₀+dx, and the function for G(x₁) may be calculated. That is,

$$G ( {x}_{1} ) = imag ( {V}_{F} ( {x}_{1} ) * conj ( {C}_{f} ( {x}_{1} ) ) ) * {I}_{0 Neg} )$$

may be calculated. At block 712A, the derivative of G(x) with respect to x may be calculated. That is,

$${G}^{′} ( x ) = ( G ( {x}_{1} ) - G ( {x}_{0} ) ) / d x$$

may be calculated. At block 714A, the first correction x_{Latest} may be calculated and the value of G(x_{Latest}) may be determined, where

$${x}_{Latest} = {x}_{0} - \frac{G ( {x}_{0} ) + G ( {x}_{1} )}{2 {G}^{′} ( x )}$$

At block 716A, the value of G(x_{Latest}) is compared to a predetermined threshold value. If the value of G(x_{Latest}) is less than the predetermined threshold, then the distance to the fault is x_{Latest}. If the value of G(x_{Latest}) is not less than the predetermined threshold, x₀ is reset to x_{Latest}, and the process restarts from block 706A.

If the fault is not a single-line-to-ground (SLG) fault, then, at block 704B, the initial value of x, x₀, may be set to half of the line length. At block 706B, V_{F}(x) and C_{f}(x) may be calculated based on the equations described herein.

$${V}_{F} ( x ) = {A}_{1} ( x ) {U}_{R} + {B}_{1} ( x ) {I}_{R}$$

$${C}_{f} = ( - {z}_{SourceL} {C}_{1} ( x ) + {D}_{1} ( x ) ) + \frac{( - {z}_{SourceR} {C}_{1} ( l - x ) + {D}_{1} ( l - x ) ) ( - {z}_{SourceL} {A}_{1} ( x ) + {B}_{1} ( x ) )}{- {z}_{SourceR} {A}_{1} ( l - x ) + {B}_{1} ( l - x )}$$

At block 708B, the function for G(x₀) may be calculated. That is,

$$G ( {x}_{0} ) = imag ( {V}_{F} ( {x}_{0} ) * conj ( {C}_{f} ( {x}_{0} ) ) ) * {jI}_{0 Neg} )$$

may be calculated. At block 710B, the value of x may be incremented from x₀ to x₁, where X₁=x₀+dx, and the function for G(x₁) may be calculated. That is,

$$G ( {x}_{1} ) = imag ( {V}_{F} ( {x}_{1} ) * conj ( {C}_{f} ( {x}_{1} ) ) ) * {jI}_{0 Neg} )$$

may be calculated. At block 712B, the derivative of G(x) with respect to x may be calculated. That is, G′(x)=(G(x₁)−G(x₀))/dx may be calculated. At block 714B, the first correction x_{Latest} may be calculated and the value of G(x_{Latest}) may be determined, where

$${x}_{Latest} = {x}_{0} - \frac{G ( {x}_{0} ) + G ( {x}_{1} )}{2 {G}^{′} ( x )}$$

At block 716B, the value of G(x_{Latest}) is compared to a predetermined threshold value. If the value of G(x_{Latest}) is less than the predetermined threshold, then the distance to the fault is x_{Latest}. If the value of G(x_{Latest}) is not less than the predetermined threshold, x₀ is reset to x_{Latest}, and the process restarts from block 706B.

Once the distance to the fault has been determined, a control action may be performed based on the determination of the distance to the fault. For example, the control action may involve the generation of an alert to an operator.

It should be apparent that the foregoing relates only to certain embodiments of this application and resultant patent. Numerous changes and modifications may be made herein by one of ordinary skill in the art without departing from the general spirit and scope of the invention as defined by the following claims and the equivalents thereof.

Further aspects of the invention are provided by the subject matter of the following clauses:

1. A method for determining a distance to a fault in a hybrid lines system, comprising: calculating, based at least in part on a set of measured voltage samples and a set of measured current samples, a first set of voltage phasors and a first set of current phasors; calculating, based at least in part on input line parameters associated with the hybrid lines system, ABCD parameters associated with the hybrid lines system; calculating, based at least in part on the first set of voltage phasors, the first set of current phasors, and the ABCD parameters, a second set of voltage phasors and a second set of current phasors; collecting, based at least in part on the second set of voltage phasors and the second set of current phasors, faulty phase voltage phasors and faulty phase current phasors; identifying, based at least in part on the faulty phase voltage phasors and the faulty phase current phasors, the fault in a faulty section of the hybrid lines system and parameters associated with the fault; and calculating, based at least in part on the parameters associated with the fault, the distance to the fault.

2. The method of clause 1, wherein the input line parameters comprise at least a line length of each section of the hybrid lines system, a positive-sequence impedance per length of the each section of the hybrid lines system, a zero-sequence impedance per length of the each section of the hybrid lines system, a positive-sequence admittance per length of the each section of the hybrid lines system, and a zero-sequence admittance per length of the each section of the hybrid lines system.

3. The method of any preceding clause, wherein the first set of voltage phasors and the first set of current phasors are calculated by applying a Fourier transform with a decaying direct current (DC) removal component to the set of measured voltage samples and the set of measured current samples.

4. The method of any preceding clause, wherein identifying the fault in the faulty section of the hybrid lines system and the parameters associated with the fault further comprises: determining that a first section of the hybrid lines system does not meet a first condition; determining that a second section of the hybrid lines system meets a second condition; and determining that the fault is located in the second section of the hybrid lines system.

5. The method of any preceding clause, wherein the first condition and the second condition are based on whether the fault is a single-phase-to-ground fault or a phase-to-phase fault, and wherein the phase-to-phase fault is associated with a real function condition, and wherein the single-phase-to-ground fault is associated with an imaginary function condition.

6. The method of any preceding clause, wherein the faulty phase voltage phasors and the faulty phase current phasors are determined based at least in part on a type of fault associated with the fault.

7. The method of any preceding clause, wherein the first set of voltage phasors and the first set of current phasors are associated with a first bus of the hybrid lines system.

8. The method of any preceding clause, wherein the second set of voltage phasors and the second set of current phasors are associated with a second bus of the hybrid lines system.

9. A method for determining a distance to a fault in a hybrid lines system, comprising: receiving a set of measured voltage samples and a set of measured current samples at a first bus of the hybrid lines system, calculating, based at least in part on the set of measured voltage samples and the set of measured current samples, a first set of voltage phasors and a first set of current phasors; receiving input line parameters associated with the hybrid lines system; calculating, based at least in part on the input line parameters, ABCD parameters associated with the hybrid lines system; calculating, based at least in part on the first set of voltage phasors, the first set of current phasors, and the ABCD parameters, a second set of voltage phasors and a second set of current phasors at a second bus of the hybrid lines system; collecting, based at least in part on the second set of voltage phasors and the second set of current phasors, faulty phase voltage phasors and faulty phase current phasors; identifying, based at least in part on the faulty phase voltage phasors and the faulty phase current phasors, the fault in a faulty section of the hybrid lines system and parameters associated with the fault; and calculating, based at least in part on the parameters associated with the fault, the distance to the fault.

10. The method of any preceding clause, wherein the input line parameters comprise at least a line length of each section of the hybrid lines system, a positive-sequence impedance per length of the each section of the hybrid lines system, a zero-sequence impedance per length of the each section of the hybrid lines system, a positive-sequence admittance per length of the each section of the hybrid lines system, and a zero-sequence admittance per length of the each section of the hybrid lines system.

11. The method of any preceding clause, wherein the first set of voltage phasors and the first set of current phasors are calculated by applying a Fourier transform with a decaying direct current (DC) removal component to the set of measured voltage samples and the set of measured current samples.

12. The method of any preceding clause, wherein identifying the fault in the faulty section of the hybrid lines system and the parameters associated with the fault further comprises: determining that a first section of the hybrid lines system does not meet a first condition; determining that a second section of the hybrid lines system meets a second condition; and determining that the fault is located in the second section of the hybrid lines system.

13. The method of any preceding clause, wherein the first condition and the second condition are based on whether the fault is a single-phase-to-ground fault or a phase-to-phase fault, and wherein the phase-to-phase fault is associated with a real function condition, and wherein the single-phase-to-ground fault is associated with an imaginary function condition.

14. The method of any preceding clause, wherein the faulty phase voltage phasors and the faulty phase current phasors are determined based at least in part on a type of fault associated with the fault.

15. A hybrid lines system, comprising: a first section having a first bus; and a second section having a second bus, wherein a first set of voltage phasors and a first set of current phasors are calculated based at least in part on a set of measured voltage samples and a set of measured current samples associated with the first section, and wherein ABCD parameters associated with the hybrid lines system are calculated based at least in part on input line parameters associated with the hybrid lines system, and wherein a second set of voltage phasors and a second set of current phasors associated with the second section are calculated based at least in part on the first set of voltage phasors, the first set of current phasors, and the ABCD parameters, and wherein faulty phase voltage phasors and faulty phase current phasors are collected based at least in part on the second set of voltage phasors and the second set of current phasors, and wherein a fault in a faulty section of the hybrid lines system and parameters associated with the fault are identified based at least in part on the faulty phase voltage phasors and the faulty phase current phasors.

16. The hybrid lines system of any preceding clause, wherein the input line parameters comprise at least a line length of each section of the hybrid lines system, a positive-sequence impedance per length of the each section of the hybrid lines system, a zero-sequence impedance per length of the each section of the hybrid lines system, a positive-sequence admittance per length of the each section of the hybrid lines system, and a zero-sequence admittance per length of the each section of the hybrid lines system.

17. The hybrid lines system of any preceding clause, wherein the first set of voltage phasors and the first set of current phasors are calculated by applying a Fourier transform with a decaying direct current (DC) removal component to the set of measured voltage samples and the set of measured current samples.

18. The hybrid lines system of any preceding clause, wherein the identification of the fault in the faulty section of the hybrid lines system and the parameters associated with the fault further comprises: determining that the first section of the hybrid lines system does not meet a first condition; determining that the second section of the hybrid lines system meets a second condition; and determining that the fault is located in the second section of the hybrid lines system.

19. The hybrid lines system of any preceding clause, wherein the first condition and the second condition are based on whether the fault is a single-phase-to-ground fault or a phase-to-phase fault, and wherein the phase-to-phase fault is associated with a real function condition, and wherein the single-phase-to-ground fault is associated with an imaginary function condition.

20. The hybrid lines system of any preceding clause, wherein the faulty phase voltage phasors and the faulty phase current phasors are determined based at least in part on a type of fault associated with the fault.

We claim:

1. A method for determining a distance to a fault in a hybrid lines system, comprising:
calculating, based at least in part on a set of measured voltage samples and a set of measured current samples, a first set of voltage phasors and a first set of current phasors;
calculating, based at least in part on input line parameters associated with the hybrid lines system, ABCD parameters associated with the hybrid lines system;
calculating, based at least in part on the first set of voltage phasors, the first set of current phasors, and the ABCD parameters, a second set of voltage phasors and a second set of current phasors;
collecting, based at least in part on the second set of voltage phasors and the second set of current phasors, faulty phase voltage phasors and faulty phase current phasors;
identifying, based at least in part on the faulty phase voltage phasors and the faulty phase current phasors, the fault in a faulty section of the hybrid lines system and parameters associated with the fault; and
calculating, based at least in part on the parameters associated with the fault, the distance to the fault.

2. The method of claim 1, wherein the input line parameters comprise at least a line length of each section of the hybrid lines system, a positive-sequence impedance per length of the each section of the hybrid lines system, a zero-sequence impedance per length of the each section of the hybrid lines system, a positive-sequence admittance per length of the each section of the hybrid lines system, and a zero-sequence admittance per length of the each section of the hybrid lines system.

3. The method of claim 1, wherein the first set of voltage phasors and the first set of current phasors are calculated by applying a Fourier transform with a decaying direct current (DC) removal component to the set of measured voltage samples and the set of measured current samples.

4. The method of claim 1, wherein identifying the fault in the faulty section of the hybrid lines system and the parameters associated with the fault further comprises:
determining that a first section of the hybrid lines system does not meet a first condition;
determining that a second section of the hybrid lines system meets a second condition; and
determining that the fault is located in the second section of the hybrid lines system.

5. The method of claim 4, wherein the first condition and the second condition are based on whether the fault is a single-phase-to-ground fault or a phase-to-phase fault, and wherein the phase-to-phase fault is associated with a real function condition, and wherein the single-phase-to-ground fault is associated with an imaginary function condition.

6. The method of claim 1, wherein the faulty phase voltage phasors and the faulty phase current phasors are determined based at least in part on a type of fault associated with the fault.

7. The method of claim 1, wherein the first set of voltage phasors and the first set of current phasors are associated with a first bus of the hybrid lines system.

8. The method of claim 7, wherein the second set of voltage phasors and the second set of current phasors are associated with a second bus of the hybrid lines system.

9. A method for determining a distance to a fault in a hybrid lines system, comprising:
receiving a set of measured voltage samples and a set of measured current samples at a first bus of the hybrid lines system,
calculating, based at least in part on the set of measured voltage samples and the set of measured current samples, a first set of voltage phasors and a first set of current phasors;
receiving input line parameters associated with the hybrid lines system;
calculating, based at least in part on the input line parameters, ABCD parameters associated with the hybrid lines system;
calculating, based at least in part on the first set of voltage phasors, the first set of current phasors, and the ABCD parameters, a second set of voltage phasors and a second set of current phasors at a second bus of the hybrid lines system;
collecting, based at least in part on the second set of voltage phasors and the second set of current phasors, faulty phase voltage phasors and faulty phase current phasors;
identifying, based at least in part on the faulty phase voltage phasors and the faulty phase current phasors, the fault in a faulty section of the hybrid lines system and parameters associated with the fault; and
calculating, based at least in part on the parameters associated with the fault, the distance to the fault.

10. The method of claim 9, wherein the input line parameters comprise at least a line length of each section of the hybrid lines system, a positive-sequence impedance per length of the each section of the hybrid lines system, a zero-sequence impedance per length of the each section of the hybrid lines system, a positive-sequence admittance per length of the each section of the hybrid lines system, and a zero-sequence admittance per length of the each section of the hybrid lines system.

11. The method of claim 9, wherein the first set of voltage phasors and the first set of current phasors are calculated by applying a Fourier transform with a decaying direct current (DC) removal component to the set of measured voltage samples and the set of measured current samples.

12. The method of claim 9, wherein identifying the fault in the faulty section of the hybrid lines system and the parameters associated with the fault further comprises:
determining that a first section of the hybrid lines system does not meet a first condition;
determining that a second section of the hybrid lines system meets a second condition; and
determining that the fault is located in the second section of the hybrid lines system.

13. The method of claim 12, wherein the first condition and the second condition are based on whether the fault is a single-phase-to-ground fault or a phase-to-phase fault, and wherein the phase-to-phase fault is associated with a real function condition, and wherein the single-phase-to-ground fault is associated with an imaginary function condition.

14. The method of claim 9, wherein the faulty phase voltage phasors and the faulty phase current phasors are determined based at least in part on a type of fault associated with the fault.

15. A hybrid lines system, comprising:
a first section having a first bus; and
a second section having a second bus,
wherein a first set of voltage phasors and a first set of current phasors are calculated based at least in part on a set of measured voltage samples and a set of measured current samples associated with the first section,
and wherein ABCD parameters associated with the hybrid lines system are calculated based at least in part on input line parameters associated with the hybrid lines system,
and wherein a second set of voltage phasors and a second set of current phasors associated with the second section are calculated based at least in part on the first set of voltage phasors, the first set of current phasors, and the ABCD parameters,
and wherein faulty phase voltage phasors and faulty phase current phasors are collected based at least in part on the second set of voltage phasors and the second set of current phasors,
and wherein a fault in a faulty section of the hybrid lines system and parameters associated with the fault are identified based at least in part on the faulty phase voltage phasors and the faulty phase current phasors.

16. The hybrid lines system of claim 15, wherein the input line parameters comprise at least a line length of each section of the hybrid lines system, a positive-sequence impedance per length of the each section of the hybrid lines system, a zero-sequence impedance per length of the each section of the hybrid lines system, a positive-sequence admittance per length of the each section of the hybrid lines system, and a zero-sequence admittance per length of the each section of the hybrid lines system.

17. The hybrid lines system of claim 15, wherein the first set of voltage phasors and the first set of current phasors are calculated by applying a Fourier transform with a decaying direct current (DC) removal component to the set of measured voltage samples and the set of measured current samples.

18. The hybrid lines system of claim 15, wherein the identification of the fault in the faulty section of the hybrid lines system and the parameters associated with the fault further comprises:
determining that the first section of the hybrid lines system does not meet a first condition;
determining that the second section of the hybrid lines system meets a second condition; and
determining that the fault is located in the second section of the hybrid lines system.

19. The hybrid lines system of claim 18, wherein the first condition and the second condition are based on whether the fault is a single-phase-to-ground fault or a phase-to-phase fault, and wherein the phase-to-phase fault is associated with a real function condition, and wherein the single-phase-to-ground fault is associated with an imaginary function condition.

20. The hybrid lines system of claim 15, wherein the faulty phase voltage phasors and the faulty phase current phasors are determined based at least in part on a type of fault associated with the fault.
